(19) United States
(12) Patent Application Publication
(10) Pub. No.: US 2009/0033523 A1
(43) Pub. Date: Feb. 5, 2009

(54) Language Input System and Method Based on Graphic Symbols

(76) Inventor: Hoon Kyu Park, Los Angeles, CA (US)

Correspondence Address: PARK LAW FIRM, 3255 WILSHIRE BLVD, SUITE 1110, LOS ANGELES, CA, 90010, US

(21) Appl. No.: 11/833,420

(22) Filed: Aug. 3, 2007

(51) Int. Cl. H03M 7/00

(52) U.S. Cl. 341/28

(57) ABSTRACT

A language input system and method of a language input apparatus according to which characters are inputted based on their graphic symbols implemented on a keypad of a language input apparatus is disclosed. The language input system facilitates entry of an input string into the mobile phone using discrete keys on a keypad, and the language input system converts a combination of one or more graphic symbols inputted by the keypad onto a letter of alphabet of a language or a writing system by a surjective concatenation mapping from a set of graphic symbols onto a set of graphic symbols of English, German or Spanish language. The set of graphic symbols of the language input system and method includes a subset of graphic symbols of any geometric shape of a line, a half circle, or a combination of lines and circles, and each geometric symbol is printed on each key of the keypad.

### BACKGROUND OF THE INVENTION

The present invention relates to a language input system and method of a language input apparatus according to which characters are inputted based on their graphic symbols implemented on a keypad of a mobile device for more comfortable recognizing and faster memorizing.

A preferred embodiment of the present invention is onto mobile devices. Examples of mobile devices are mobile phones, personal digital assistants (PDAs), handheld computers, handheld game consoles, handheld televisions, and the like. One possible implementation of a mobile device is a mobile phone.

Referring to FIG. 1, a mobile phone 100 by prior art for inputting English language includes a body 110, a display 120, in which letters of English alphabet, numbers, and other symbols are displayed on a liquid crystal display (LCD) screen according to input string via a keypad 140 implemented as a 10-key numeric keypad, navigation keys 130, which are located above the keypad 140 for additional controls of the mobile phone 100, an antenna 150, which is a conductor for radiating and receiving radio waves, and a power source, i.e., a battery 160.

Referring to FIG. 2, an electronic device for the mobile phone 100 by prior art includes an application-specific integrated circuit (ASIC) 170, which is an integrated circuit designed for a particular use. The application-specific integrated circuit (ASIC) includes a microprocessor 171, which is a non-memory central processing unit (CPU), a volatile memory (VM) 172, which is a memory device that loses stored data when power is turned off (e.g., most of random access memory (RAM)), and a non-volatile memory (NVM) 173, which is a memory device that retains stored information even if power is removed (e.g., read-only memory (ROM), flash memory, magnetic computer storage devices, optical disk drives, etc.), in which the non-volatile memory (NVM) contains a language input system 1731 that converts input string of English alphabet and numbers into string of English alphabet and numbers based on an implemented program. The display 120, the keypad 140, the microprocessor 171, the volatile memory 172, and the non-volatile memory 173 are interconnected via a bus 180 for transferring data between components.

On the other hand, a category C of alphabets consists of a class Object(C) of objects, where an object is an alphabet, which is a finite set with elements from countable symbols of a language or a writing system, a class Morphism(C) of functions, where a function is a concatenation of finite sequence of letters of an alphabet, and a Composition(C) of functions for any three objects satisfying axioms of associativity and identity. A series of concatenations makes a string of letters and eventually forms a language or a writing system.

In phonetic languages (e.g., Chinese Pinyin, English, French, German, etc.) a language input system is simpler than character-based languages (e.g., Chinese Hanzi, Korean Hangul, etc.) due to relatively small number of phonetic letters, even if both language types make a user difficult to input characters of their intents into mobile devices.

The entry of phonetic text is difficult on a keypad having a small number of keys on a keypad of mobile devices. As an example, for inputting English language a mobile phone typically has 8 keys to represent 26 letters in an object of English alphabet via numeric keys 2 through 9. There are several approaches for inputting English alphabet into a mobile device. For Chinese characters Q9 input system is an input system that utilizes structure of characters.

An approach for inputting English alphabet is a multiple keystroke approach, which is to depress the same key one or more times to input letters of English alphabet. For instance, referring to FIG. 1, a user presses a “2” key one time to enter a letter A, presses the same key two times to enter a letter B, presses the same key three times to enter a letter C, and so on. The choice of upper of lower case letters can be made by pressing “*” key one or more times.

Another typical approach is a predictive text input system for mobile devices. This approach is more convenient than multiple keystroke approach because the predictive text input system allows words to be entered by a single keystroke for each letter as opposed to multiple keystroke approach. For example, T9 system, where T9 stands for “Text on 9 keys”, is one of predictive text input technologies for mobile devices. The T9 system facilitates entry of a word into a mobile device by tapping one key per letter. T9 system tries to find matching words while typing and displays words of possible matches. A user selects a word of his/her intention out of possible matches made by T9 input system. If the intended word is not in a dictionary of T9 system, then a user has an option to add and save the word onto the T9 system for future use.

However, approaches of English alphabet input system by prior art have a disadvantage that a user may not notice each letter comfortably because each numeric key contains three letters of English alphabet, so that a user has difficulty in recognizing, memorizing, and being accustomed to letters in a keypad in a short time.

### SUMMARY OF THE INVENTION

The present invention contrives to solve the above disadvantages of the prior art. An objective of the present invention is to make a user remember or recognize each letter of English alphabet more comfortably and conveniently via a method of graphic symbols. Each symbol is established from a basic curve of each letter of English alphabet in calligraphy, so that a user does need to pay little effort to be accustomed to graphic symbols for complete mastering.

Another objective of the invention is to assign symbols onto a keypad to let a user memorize in a short time. A user uses limited number of fingers (e.g., a finger of one hand, thumbs of both hands, etc.) in a keypad of small size to input characters of his/her intent, so that fast memorizing of each symbol's location is more important than a method of assigning graphic symbols through an analysis of efficient usage of many fingers and moving path of each finger.

Still another object of the invention is to simplify graphic forms of letters of English lowercase alphabet and analyze each factor to symbolize English alphabet. This method is for implementing all letters of English alphabet into a mobile device by means of a 11-key symbolic keypad.

In order to accomplish the above objectives of the invention, disclosed is a language input apparatus including a keypad of keys, in which the keys have associated graphic symbols, a language input system to receive an input string of graphic symbols entered via the keypad of the language input apparatus and generate corresponding graphic symbols of a language or a writing system by a concatenation mapping from a set of graphic symbols onto a set of graphic symbols of the language or the writing system, and a display to present the corresponding graphic symbols of the language or the writing system, in which the set of graphic symbols includes a subset of graphic symbols of any geometric shape of a line, a half circle, and a combination of lines and half circles. The subset of the graphic symbols of the language input apparatus further includes [symbol] -shape, *-shape, #-shape, and numerals.

A string of graphic symbols of the language or the writing system is formed by a concatenation mapping from a set of graphic symbols of the language or the writing system into a set of graphic symbols of the language or the writing system to form a string of graphic symbols of the language or the writing system. The set of graphic symbols of the language or the writing system includes letters of alphabet or characters of the language or the writing system, numerals, and typographic symbols. Each graphic symbol is printed on each key of the keypad.

More specifically, the subset of the graphic symbols of the language input apparatus includes a right-slanted line, a horizontal line, a left-slanted line, a left half circle, a vertical line, a right half circle, an upper half circle, a V-shape, a lower half circle, and a circle with -shape. The subset of the graphic symbols of the language input apparatus further includes [symbol] -shape, *-shape, #-shape, and numerals.

The set of graphic symbols of the language or the writing system of the language input apparatus includes a set of letters of English alphabet, numerals, and typographic symbols. The concatenation mapping from the subset of graphic symbols onto a set of lowercase letters of English alphabet, numerals and typographic symbols is represented by table of concatenations of graphic symbols in FIG. 6. The concatenation mapping from the subset of graphic symbols onto a set of uppercase letters of English alphabet includes the graphic symbol of *-shape plus each graphic symbol for the lowercase letters of English alphabet.

The set of graphic symbols of the language or the writing system of the language input apparatus further includes a set of letters of German alphabet, numerals, and typographic symbols. The concatenation mapping from the subset of graphic symbols onto a set of lowercase letters of German alphabet, numerals, and typographic symbols is represented by table of concatenations of graphic symbols in FIG. 7. The concatenation mapping from the subset of graphic symbols onto a set of uppercase letters of German alphabet includes the graphic symbol of *-shape plus each graphic symbol for the lowercase letters of German alphabet.

The set of graphic symbols of the language or the writing system of the language input apparatus further includes a set of letters of Spanish alphabet, numerals, and typographic symbols. The concatenation mapping from the subset of graphic symbols onto a set of lowercase letters of Spanish alphabet, numerals, and typographic symbols is represented by table of concatenations of graphic symbols in FIG. 8. The concatenation mapping from the subset of graphic symbols onto a set of uppercase letters of Spanish alphabet includes the graphic symbol of *-shape plus each graphic symbol for the lowercase letters of Spanish alphabet.

The invention also provides a language input method including step of receiving an input string entered via the keypad of the language input apparatus that is representative of one or more graphic symbols and step of generating corresponding graphic symbols of a language or a writing system by a concatenation mapping from a set of graphic symbols onto a set of graphic symbols of the language or the writing system, in which the set of graphic symbols includes a subset of graphic symbols of any geometric shape of a line, a half circle, or a combination of lines and half circles. The subset of the graphic symbols of the language input method further includes [symbol] -shape, *-shape, #-shape, and numerals.

A string of graphic symbols of the language or the writing system is formed by a concatenation mapping from a set of graphic symbols of the language or the writing system into a set of graphic symbols of the language or the writing system to form a string of graphic symbols of the language or the writing system. The set of graphic symbols of the language or the writing system includes letters of alphabet or characters of the language or the writing system, numerals, and typographic symbols. Each graphic symbol is printed on each key of the keypad.

More specifically, the subset of the graphic symbols of the language input method includes a right-slanted line, a horizontal line, a left-slanted line, a left half circle, a vertical line, a right half circle, an upper half circle, a V-shape, a lower half circle, and a circle with -shape. The subset of the graphic symbols of the language input method further includes [symbol] -shape, *-shape, #-shape, and numerals.

The set of graphic symbols of the language or the writing system of the language input method includes a set of letters of English alphabet, numerals, and typographic symbols. The concatenation mapping from the subset of graphic symbols onto a set of lowercase letters of English alphabet, numerals, and typographic symbols is represented by table of concatenations of graphic symbols in FIG. 6. The concatenation mapping from the subset of graphic symbols onto a set of uppercase letters of English alphabet includes the graphic symbol of *-shape plus each graphic symbol for the lowercase letters of English alphabet.

The set of graphic symbols of the language or the writing system of the language input method further includes a set of letters of German alphabet, numerals, and typographic symbols. The concatenation mapping from the subset of graphic symbols onto a set of lowercase letters of German alphabet, numerals, and typographic symbols is represented by table of concatenations of graphic symbols in FIG. 7. The concatenation mapping from the subset of graphic symbols onto a set of uppercase letters of German alphabet includes the graphic symbol of *-shape plus each graphic symbol for the lowercase letters of German alphabet.

The set of graphic symbols of the language or the writing system of the language input method further includes a set of letters of Spanish alphabet, numerals, and typographic symbols. The concatenation mapping from the subset of graphic symbols onto a set of lowercase letters of Spanish alphabet, numerals, and typographic symbols is represented by table of concatenations of graphic symbols in FIG. 8. The concatenation mapping from the subset of graphic symbols onto a set of uppercase letters of Spanish alphabet includes the graphic symbol of *-shape plus each graphic symbol for the lowercase letters of Spanish alphabet.

An advantageous effect of the invention is that a user remembers or recognizes each letter of English alphabet more comfortably and conveniently via a method of graphic symbols. Each symbol is established from a basic curve of each letter of English alphabet in calligraphy, so that a user does need to pay little effort to be accustomed to graphic symbols for complete mastering.

Another advantageous effect of the invention is that symbols are assigned onto a keypad to let a user memorize in a short time. A user uses limited number of fingers (e.g., a finger of one hand, thumbs of both hands, etc.) in a keypad of small size to input characters of his/her intent, so that fast memorizing of each symbol's location is more important than a method of assigning graphic symbols through an analysis of efficient usage of many fingers and moving path of each finger.

Still another advantageous effect of the invention is that graphic forms of letters of English lowercase alphabet are simplified and analyzed to symbolize English alphabet. This method is for implementing all letters of English alphabet into a mobile device by means of a 11-key symbolic keypad.

### BRIEF DESCRIPTION OF THE DRAWINGS

These and other features, aspects and advantages of the present invention will become better understood with reference to the accompanying drawings, wherein:

FIG. 1 is an elevation view of the mobile phone by prior art.

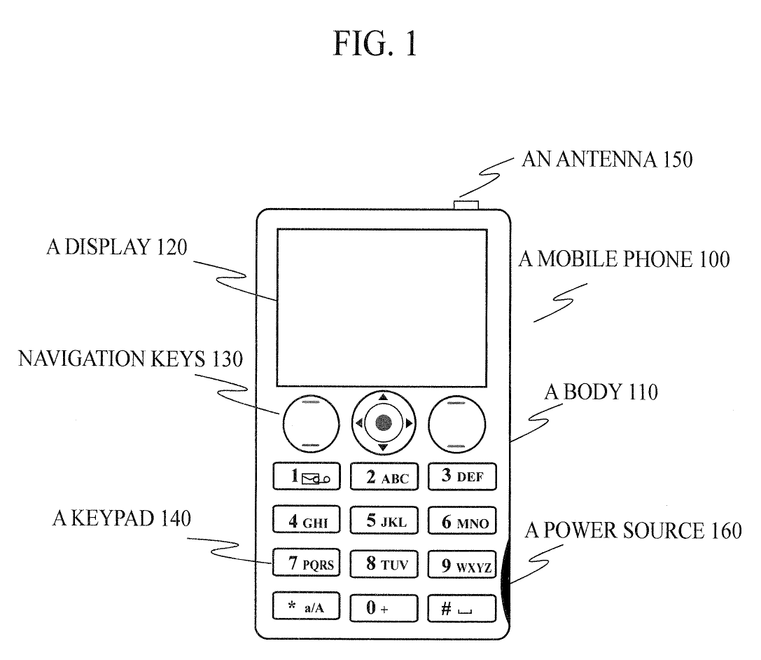

FIG. 2 is a block diagram of the mobile phone by prior art.

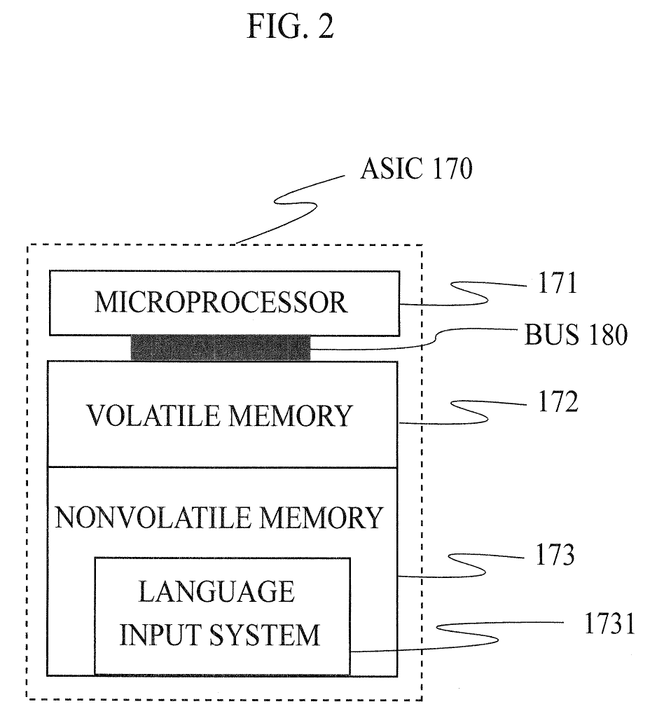

FIG. 3 is an elevation view of a mobile phone according to the present invention.

FIG. 4 is a block diagram of the mobile phone according to the present invention.

FIG. 5 is a schematic diagram showing graphic symbols of a keypad for the mobile phone according to the present invention.

FIG. 6 is a schematic diagram showing a mapping from a set of graphic symbols of the present invention onto a set of lowercase letters of English alphabet, numerals and typographic symbols.

FIG. 7 is a schematic diagram showing a mapping from a set of graphic symbols of the present invention onto a set of lowercase letters of German alphabet, numerals and typographic symbols.

FIG. 8 is a schematic diagram showing a mapping from a set of graphic symbols of the present invention onto a set of lowercase letters of Spanish alphabet, numerals and typographic symbols.

### DETAILED DESCRIPTION OF THE PREFERRED EMBODIMENT

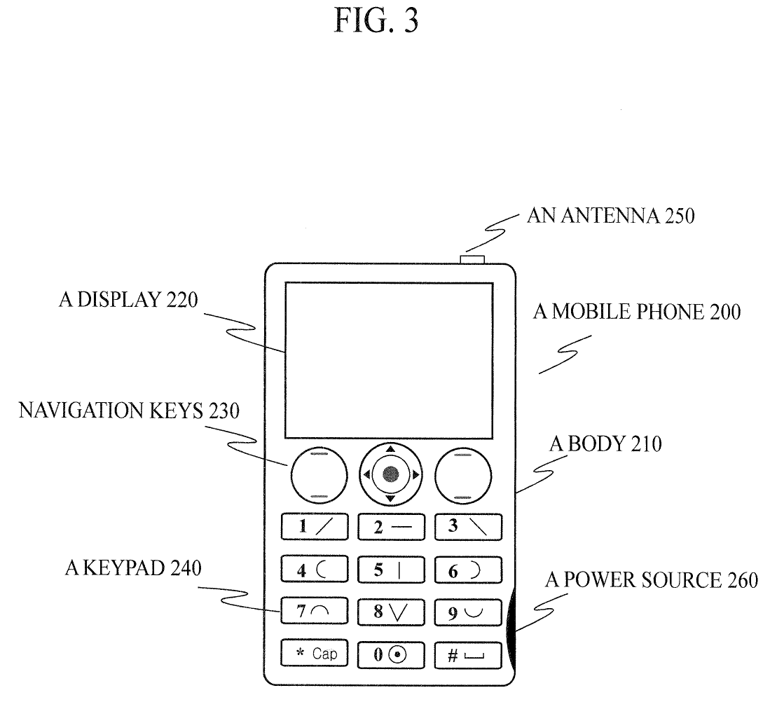

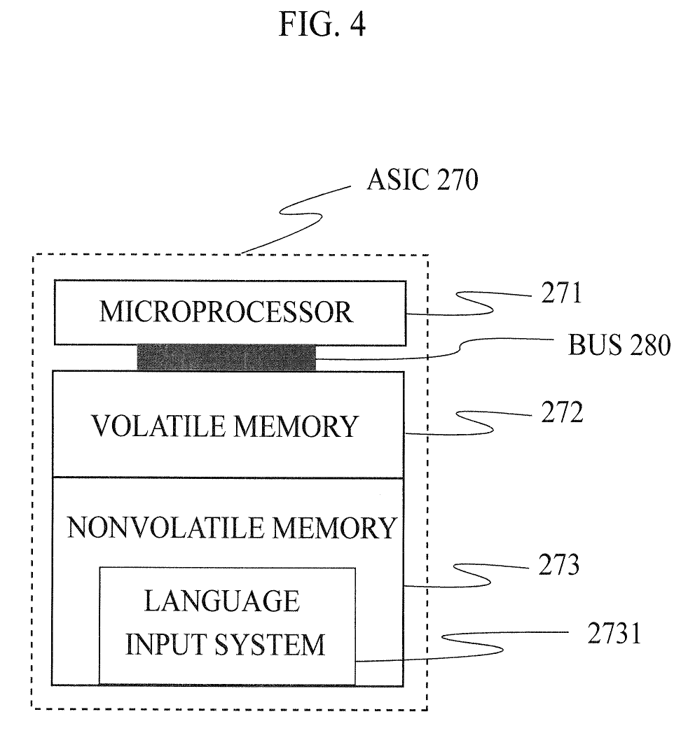

FIG. 3 and FIG. 4 show a preferred embodiment of a mobile device implemented English language input system according to the present invention. Referring to FIG. 3, a mobile phone 200 of the present invention includes a body 210, a display 220, in which letters of English alphabet are displayed according to input of graphic symbols via a keypad 240 implemented as a 12-key keypad of graphic symbols, navigation keys 230, which is located above the keypad 240 for additional controls of the mobile phone, an antenna 250, which is a conductor for radiating and receiving radio waves, and a power source, i.e., a battery 260.

Referring to FIG. 4, an electronic device for the mobile phone 200 of the present invention includes an application-specific integrated circuit (ASIC) 270, which is an integrated circuit designed for a particular use. The application-specific integrated circuit (ASIC) includes a microprocessor 271, which is a non-memory central processing unit (CPU), a volatile memory (VM) 272, which is a memory device that loses stored data when power is turned off (e.g., most of random access memory (RAM)), and a non-volatile memory (NVM) 273, which is a memory device that retains stored information even if power is removed (e.g., read-only memory (ROM), flash memory, magnetic computer storage devices, optical disk drives, etc.), in which the non-volatile memory (NVM) contains a language input system 2731 that converts input string of graphic symbols into string of English alphabet, numbers, and symbols based on an implemented program. The display 220, the keypad 240, the microprocessor 271, the volatile memory 272, and the non-volatile memory 273 are interconnected via a bus 280 for transferring data between components.

In the language input system based on symbols implemented with a category C of alphabets, there exists a surjective concatenation mapping from an object of graphic symbols onto an object of English alphabet, where the mapping is a concatenation of finite sequence of graphic symbols, followed by a concatenation mapping from an object of English alphabet into an object of English alphabet to form a string of English alphabet, where an object of graphic symbols is regarded as an object of an alphabet and an implementation of the surjective concatenation mapping is defined in the following paragraphs. The composition of the two mappings exists according to Composition(C) of functions in the category C of alphabets. A series of concatenations makes a string of letters and eventually forms a English language or a English writing system.

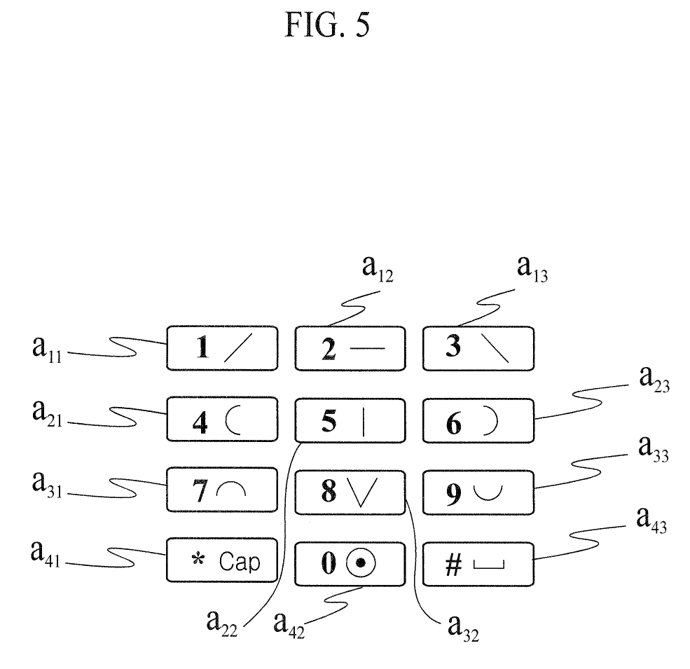

The keypad 240 has an implementation of graphic symbols onto each discrete keys referring to FIG. 5. Each key location is represented as a matrix {aᵢⱼ}, where i is an element selected from a set of a positive integer from 1 to 4 representing pertinent row of each keypad, j is an element selected from a set of a positive integer from 1 to 3 representing pertinent column of each keypad, and aᵢⱼ is an abstraction of each location of a discrete key in a keypad for each i and j. In other words, there exists one-to-one correspondence between a set of keys in a keypad onto the set of matrices {aᵢⱼ} without specifying each element of the set of matrices {aᵢⱼ}. Therefore, any permutation of elements of the set of each matrix is possible for different implementations.

An example of a possible implementation is as follows: a graphic symbol of “a right-slanted line” together with a number “1” is printed on a key all, a graphic symbol of “a horizontal line” together with a number “2” is printed on a key a₁₂, a graphic symbol of “a left-slanted line” together with a number “3” is printed on a key a₁₃, a graphic symbol of “a left half circle” together with a number “4” is printed on a key a₂₁, a graphic symbol of “a vertical line” together with a number “5” is printed on a key a₂₂, a graphic symbol of “a right half circle” together with a number “6” is printed on a key a₂₃, a graphic symbol of “a upper half circle” together with a number “7” is printed on a key a₃₁, a graphic symbol of “V-shape” together with a number “8” is printed on a key a₃₂, a graphic symbol of “a lower half circle” together with a number “9” is printed on a key a₃₃, a graphic symbol of “*-shape” together with a word “Cap” is printed on a key a₄₁, a graphic symbol of “a circle with -shape” together with a number “0” is printed on a key a₄₂, and a graphic symbol of “#-shape” together with a graphic symbol of “a space bar or [symbol] -shape” is printed on a key a₄₃.

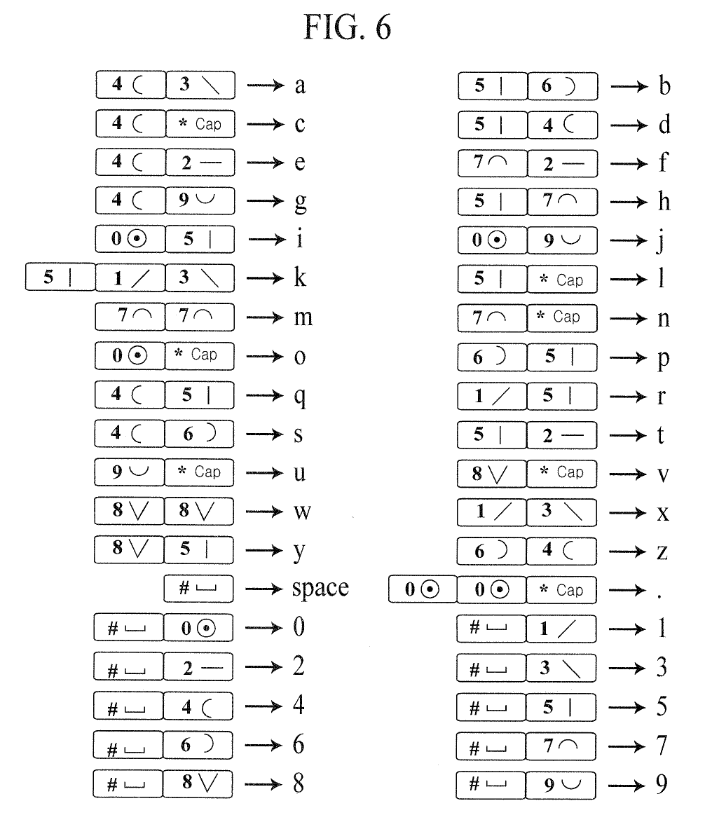

The language input system 2731 facilitates entry of an input string into the mobile phone using discrete keys on the keypad 240. The language input system 2731 automatically converts a combination of one or more graphic symbols inputted by the keypad 240 onto a letter of English lowercase alphabet by a surjective concatenation mapping from an object of graphic symbols onto an object of English alphabet. The implementation of letters of English alphabet, numbers, and typographic characters are schematically drawn and explained in FIG. 6. The surjective concatenation mapping is defined as in the next paragraph referring to FIG. 6, where the mapping is from one, two or three elements in an object of graphic symbols to an element in an object of English alphabet and the ordering among elements in an object of graphic symbols is defined from an ordinal set of {1,2} or {1,2,3} without allowing any permutation of elements.

A combination of a graphic symbol of “a left half circle” and a graphic symbol of “a left-slanted line” is mapped onto a letter a of English alphabet, a combination of a graphic symbol of “a vertical line” and a graphic symbol of “a right half circle” is mapped onto a letter b of English alphabet, a combination of a graphic symbol of “a left half circle” and a graphic symbol of “*-shape” is mapped onto a letter c of English alphabet, a combination of a graphic symbol of “a vertical line” and a graphic symbol of “a left half circle” is mapped onto a letter d of English alphabet, a combination of a graphic symbol of “a left half circle” and a graphic symbol of “a horizontal line” is mapped onto a letter e of English alphabet, a combination of a graphic symbol of “an upper half circle” and a graphic symbol of “a horizontal line” is mapped onto a letter f of English alphabet, a combination of a graphic symbol of “a left half circle” and a graphic symbol of “a lower half circle” is mapped onto a letter g of English alphabet, a combination of a graphic symbol of “a vertical line” and a graphic symbol of “a upper half circle” is mapped onto a letter h of English alphabet, a combination of a graphic symbol of “a circle with -shape” and a graphic symbol of “a vertical line” is mapped onto a letter i of English alphabet, a combination of a graphic symbol of “a circle with shape” and a graphic symbol of “a lower half circle” is mapped onto a letter j of English alphabet, a combination of a graphic symbol of “a vertical line”, a graphic symbol of “a right-slanted line”, and a graphic symbol of “a left-slanted line” is mapped onto a letter k of English alphabet, a combination of a graphic symbol of “a vertical line” and a graphic symbol of “*-shape” is mapped onto a letter I of English alphabet, a combination of a graphic symbol of “a upper half circle” and a graphic symbol of “a upper half circle” is mapped onto a letter m of English alphabet, a combination of a graphic symbol of “a upper half circle” and a graphic symbol of “*-shape” is mapped onto a letter n of English alphabet, a combination of a graphic symbol of “a circle with -shape” and a graphic symbol of “*-shape” is mapped onto a letter o of English alphabet, a combination of a graphic symbol of “a right half circle” and a graphic symbol of “a vertical line” is mapped onto a letter p of English alphabet, a combination of a graphic symbol of “a left half circle” and a graphic symbol of “a vertical line” is mapped onto a letter q of English alphabet, a combination of a graphic symbol of “a right slanted line” and a graphic symbol of “a vertical line” is mapped onto a letter r of English alphabet, a combination of a graphic symbol of “a left half circle” and a graphic symbol of “a right half circle” is mapped onto a letter s of English alphabet, a combination of a graphic symbol of “a vertical line” and a graphic symbol of “a horizontal line” is mapped onto a letter t of English alphabet, a combination of a graphic symbol of “a lower half circle” and a graphic symbol of “*-shape” is mapped onto a letter u of English alphabet, a combination of a graphic symbol of “V-shape” and a graphic symbol of “*-shape” is mapped onto a letter v of English alphabet, a combination of a graphic symbol of “V-shape” and a graphic symbol of “V-shape” is mapped onto a letter w of English alphabet, a combination of a graphic form of “a right-slanted line” and a graphic symbol of “a left-slanted line” is mapped onto a letter x of English alphabet, a combination of a graphic symbol of “V-shape” and a graphic symbol of “a vertical line” is mapped onto a letter y of English alphabet, and a combination of a graphic symbol of “a right half circle” and a graphic symbol of “a left half circle” is mapped onto a letter z of English alphabet.

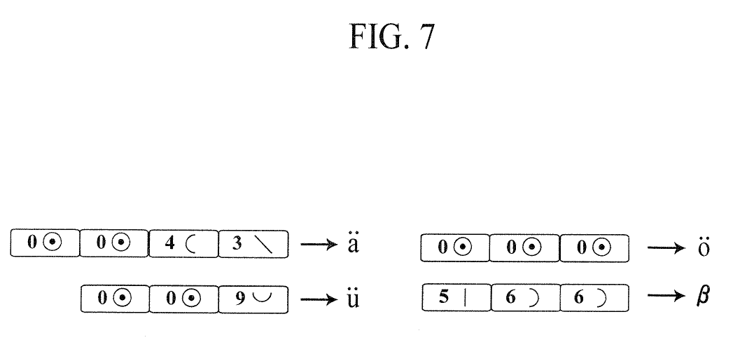

The language input system 2731 further automatically converts a combination of one or more graphic symbols inputted by the keypad 240 onto a letter of German lowercase alphabet by a surjective concatenation mapping from an object of graphic symbols onto an object of graphic symbols of German alphabet, numerals and typographic symbols. The implementation of letters of German alphabet, numerals and typographic symbols are schematically drawn and explained in FIG. 7. The surjective concatenation mapping is defined as in the next paragraph referring to FIG. 7, where the mapping is from one, two, three or four elements in an object of graphic symbols to an element in an object of German alphabet, numerals and typographic sysmbols and the ordering among elements in an object of graphic symbols is defined from an ordinal set of {1,2}, {1,2,3} or {1,2,3,4} without allowing any permutation of elements.

In addition to the mappings defined in FIG. 6, a combination of a graphic symbol of “a circle with -shape”, a graphic symbol of “a circle with -shape”, a graphic symbol of “a left half circle”, and a graphic symbol of “a left-slanted line” is mapped onto a letter a (a with umlaut) of German alphabet, a combination of a graphic symbol of “a circle with -shape”, a graphic symbol of “a circle with -shape”, and a graphic symbol of “a circle with -shape” is mapped onto a letter ö (o with umlaut) of German alphabet, a combination of a graphic symbol of “a circle with -shape”, a graphic symbol of “a circle with -shape”, and a graphic symbol of “a lower half circle” is mapped onto a letter ii (u with umlaut) of German alphabet, and a combination of a graphic symbol of “a vertical line”, a graphic symbol of “a right-half circle”, and a graphic symbol of “a right half circle” is mapped onto a letter β, (es-zett) of German alphabet.

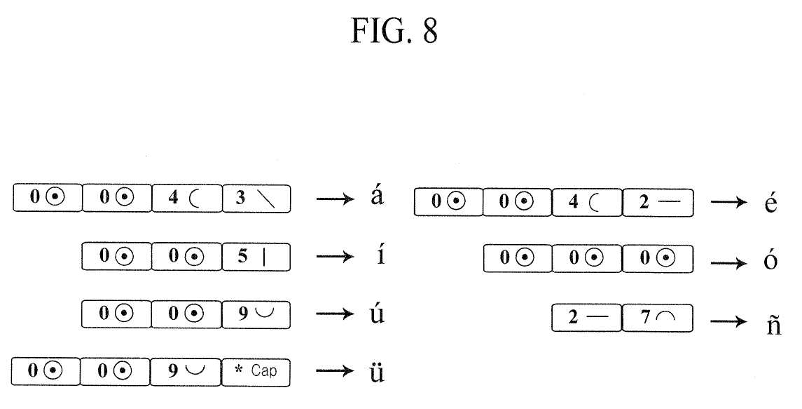

The language input system 2731 further automatically converts a combination of one or more graphic symbols inputted by the keypad 240 onto a letter of Spanish lowercase alphabet by a surjective concatenation mapping from an object of graphic symbols onto an object of graphic symbols of Spanish alphabet, numerals and typographic symbols. The implementation of letters of Spanish alphabet, numerals and typographic symbols are schematically drawn and explained in FIG. 8. The surjective concatenation mapping is defined as in the next paragraph referring to FIG. 8, where the mapping is from one, two, three or four elements in an object of graphic symbols to an element in an object of Spanish alphabet, numerals and typographic sysmbols and the ordering among elements in an object of graphic symbols is defined from an ordinal set of {1,2}, {1,2,3} or {1,2,3,4} without allowing any permutation of elements.

In addition to the mappings defined in FIG. 6, a combination of a graphic symbol of “a circle with -shape”, a graphic symbol of “a circle with -shape”, a graphic symbol of “a left half circle”, and a graphic symbol of “a left-slanted line” is mapped onto a letter a (a with acute accent) of Spanish alphabet, a combination of a graphic symbol of “a circle with -shape”, a graphic symbol of “a circle with -shape”, a graphic symbol of “a left half circle”, and a graphic symbol of “a horizontal line” is mapped onto a letter é (e with acute accent) of Spanish alphabet, a combination of a graphic symbol of “a circle with -shape”, a graphic symbol of “a circle with -shape”, and a graphic symbol of “a vertical line” is mapped onto a letter í (i with acute accent) of Spanish alphabet, a combination of a graphic symbol of “a circle with -shape”, a graphic symbol of “a circle with -shape”, and a graphic symbol of “a circle with -shape” is mapped onto a letter ó (o with acute accent) of Spanish alphabet, a combination of a graphic symbol of “a circle with -shape”, a graphic symbol of “a circle with -shape”, and a graphic symbol of “a lower half circle” is mapped onto a letter ú (u with acute accent) of Spanish alphabet, a combination of a graphic symbol of “a horizontal line” and a graphic symbol of “an upper half circle” is mapped onto a letter ñ (n with diacritical tilde) of Spanish alphabet, and a combination of a graphic symbol of “a circle with -shape”, a combination of a graphic symbol of “a circle with -shape”, a combination of a graphic symbol of “a lower half circle”, and a graphic symbol of “*-shape” is mapped onto a letter ü (u with diaeresis) of Spanish alphabet.

Inputting letters of uppercase alphabet is same as the inputting of lowercase alphabet except further pressing a “*” or “Cap” key right before pressing the graphic symbols for lowercase letters, and this process is same in any inputting letters of uppercase alphabet of a language or a writing system.

For numbers, a combination of a graphic symbol of “#-shape” and a number “i” maps onto a letter i, in which i is an element selected from a set of nonnegative integers from 0 to 9. For inputting a blank a “#” or “Space” key is mapped into the blank letter, and for inputting a period symbol of “-shape” a combination of a graphic form of “a circle with -shape”, a graphic symbol of “a circle with -shape”, and a graphic symbol of “*-shape” is mapped onto the period symbol of “-shape”.

A user has an option to press number keys instead of pressing the graphic symbols although the graphic symbols are more convenient to use. For instance, for inputting a letter a, a user sequentially presses a combination of a key 4 and a key 3.

While the invention has been shown and described with reference to different embodiments thereof, it will be appreciated by those skilled in the art that variations in form, detail, compositions and operation may be made without departing from the spirit and scope of the invention as defined by the accompanying claims.

What is claimed is:

1. A language input apparatus comprising:
a keypad of keys, wherein the keys have associated graphic symbols;
a language input system to receive an input string of graphic symbols entered via the keypad of the language input apparatus and generate corresponding graphic symbols of a language or a writing system by a concatenation mapping from a set of graphic symbols onto a set of graphic symbols of the language or the writing system; and
a display to present the corresponding graphic symbols of the language or the writing system;
wherein the set of graphic symbols comprises of a subset of graphic symbols of any geometric shape of a line, a half circle, and a combination of lines and half circles.

2. The language input apparatus of the claim 1, wherein the subset of graphic symbols further comprises of [symbol] -shape, *-shape, #-shape, and numerals.

3. The language input apparatus of the claim 1, wherein a string of graphic symbols of the language or the writing system is formed by a concatenation mapping from a set of graphic symbols of the language or the writing system into a set of graphic symbols of the language or the writing system to form a string of graphic symbols of the language or the writing system.

4. The language input apparatus of the claim 1, wherein the set of graphic symbols of the language or the writing system comprises of letters of alphabet or characters of the language or the writing system, numerals, and typographic symbols.

5. The language input apparatus of the claim 1, wherein each graphic symbol is printed on each key of the keypad.

6. The language input apparatus of the claim 1, wherein the subset of graphic symbols comprises of a right-slanted line, a horizontal line, a left-slanted line, a left half circle, a vertical line, a right half circle, an upper half circle, a V-shape, a lower half circle, and a circle with -shape.

7. The language input apparatus of the claim 6, wherein the subset of graphic symbols further comprises of shape, -shape, #-shape, and numerals.

8. The language input apparatus of the claim 7, wherein the set of graphic symbols of the language or the writing system comprises of letters of English alphabet, numerals, and typographic symbols.

9. The language input apparatus of the claim 8, wherein the concatenation mapping from the subset of graphic symbols onto a set of lowercase letters of English alphabet, numerals, and typographic symbols is represented by the following table of concatenations of graphic symbols:

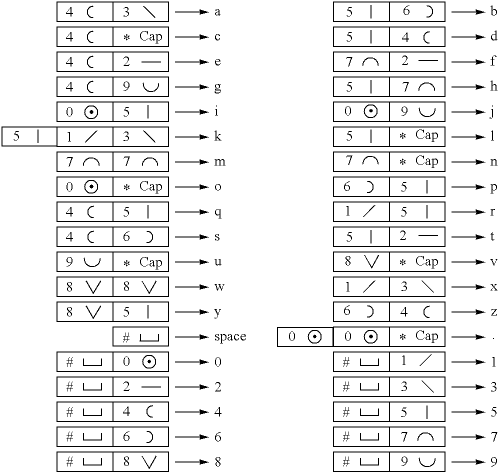

10. The language input apparatus of the claim 9, wherein the concatenation mapping from the subset of graphic symbols onto a set of uppercase letters of English alphabet comprises of the graphic symbol of *-shape plus each graphic symbol for the lowercase letters of English alphabet.

11. The language input apparatus of the claim 7, wherein the set of graphic symbols of the language or the writing system further comprises of a set of letters of German alphabet, numerals, and typographic symbols.

12. The language input apparatus of the claim 11, wherein the concatenation mapping from the subset of graphic symbols onto a set of lowercase letters of German alphabet, numerals, and typographic symbols is represented by the table of concatenations of graphic symbols of the claim 9 and the following table:

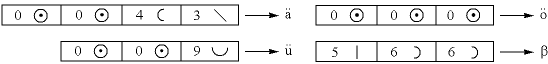

13. The language input apparatus of the claim 12, wherein the concatenation mapping from the subset of graphic symbols onto a set of uppercase letters of German alphabet comprises of the graphic symbol of *-shape plus each graphic symbol for the lowercase letters of German alphabet.

14. The language input apparatus of the claim 7, wherein the set of graphic symbols of the language or the writing system further comprises of a set of letters of Spanish alphabet, numerals, and typographic symbols.

15. The language input apparatus of the claim 14, wherein the concatenation mapping from the subset of graphic symbols onto a set of lowercase letters of Spanish alphabet, numerals, and typographic symbols is represented by the table of concatenations of graphic symbols of the claim 9 and the following table:

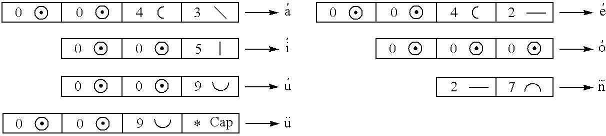

16. The language input apparatus of the claim 15, wherein the concatenation mapping from the subset of graphic symbols onto a set of uppercase letters of Spanish alphabet comprises of the graphic symbol of *-shape plus each graphic symbol for the lowercase letters of Spanish alphabet.

17. A language input method including steps of:
receiving an input string entered via a keypad of the language input apparatus that is representative of one or more graphic symbols; and
generating corresponding graphic symbols of a language or a writing system by a concatenation mapping from a set of graphic symbols onto a set of graphic symbols of the language or the writing system;
wherein the set of graphic symbols comprises of a subset of graphic symbols of any geometric shape of a line, a half circle, and a combination of lines and half circles.

18. The language input method of the claim 17, wherein the subset of graphic symbols further comprises of [symbol] -shape, *-shape, #-shape, and numerals.

19. The language input method of the claim 17, wherein a string of graphic symbols of the language or the writing system is formed by a concatenation mapping from a set of graphic symbols of the language or the writing system into a set of graphic symbols of the language or the writing system to form a string of graphic symbols of the language or the writing system.

20. The language input method of the claim 17, wherein the set of graphic symbols of the language or the writing system comprises of letters of alphabet or characters of the language or the writing system, numerals, and typographic symbols.

21. The language input method of the claim 17, wherein each graphic symbol is printed on each key of the keypad.

22. The language input method of the claim 17, wherein the subset of graphic symbols comprises of a right-slanted line, a horizontal line, a left-slanted line, a left half circle, a vertical line, a right half circle, an upper half circle, V-shape, a lower half circle, and a circle with -shape.

23. The language input method of the claim 22, wherein the subset of graphic symbols further comprises of graphic symbols of [symbol] -shape, *-shape, #-shape, and numerals.

24. The language input method of the claim 23, wherein the set of graphic symbols of the language or the writing system comprises of a set of letters of English alphabet, numerals, and typographic symbols.

25. The language input method of the claim 24, wherein the concatenation mapping from the subset of graphic symbols onto a set of lowercase letters of English alphabet, numerals and typographic symbols is represented by the table of concatenations of graphic symbols of the claim 9.

26. The language input method of the claim 25, wherein the concatenation mapping from the subset of graphic symbols onto a set of uppercase letters of English alphabet comprises of the graphic symbol of *-shape plus each graphic symbol for the lowercase letters of English alphabet.

27. The language input method of the claim 23, wherein the set of graphic symbols of the language or the writing system further comprises of a set of letters of German alphabet, numerals, and typographic symbols.

28. The language input method of the claim 27, wherein the concatenation mapping from the subset of graphic symbols onto a set of lowercase letters of German alphabet, numerals, and typographic symbols is represented by the table of concatenations of graphic symbols of the claim 9 and the table of the claim 12.

29. The language input method of the claim 28, wherein the concatenation mapping from the subset of graphic symbols onto a set of uppercase letters of German alphabet comprises of the graphic symbol of *-shape plus each graphic symbol for the lowercase letters of German alphabet.

30. The language input method of the claim 23, wherein the set of graphic symbols of the language or the writing system further comprises of a set of letters of Spanish alphabet, numerals, and typographic symbols.

31. The language input method of the claim 30, wherein the concatenation mapping from the subset of graphic symbols onto a set of lowercase letters of Spanish alphabet, numerals, and typographic symbols is represented by the table of concatenations of graphic symbols of the claim 9 and the table of the claim 15.

32. The language input method of the claim 31, wherein the concatenation mapping from the subset of graphic symbols onto a set of uppercase letters of Spanish alphabet comprises of the graphic symbol of *-shape plus each graphic symbol for the lowercase letters of Spanish alphabet.
